(19) United States
(12) Patent Application Publication
(10) Pub. No.: US 2026/0319030 A1
(43) Pub. Date: Oct. 15, 2026

(54) STRAY FIELD IMMUNE PWM-ENCODED SENSOR

(71) Applicant: Allegro MicroSystems, LLC, Manchester, NH (US)

(72) Inventors: Hernán D. Romero, Buenos Aires (AR); Bryan Cadugan, Bedford, MA (US)

(73) Assignee: Allegro MicroSystems, LLC, Manchester, NH (US)

(21) Appl. No.: 19/177,811

(22) Filed: Apr. 14, 2025

(51) Int. Cl. G01R 33/09; G01R 15/20; G01R 19/00; H03K 7/08

(52) U.S. Cl. CPC G01R 33/098; G01R 15/205; G01R 19/0092; H03K 7/08

(57) ABSTRACT

A sensor, comprising: a first magnetic field sensing element that is configured to generate a first threshold signal; a second magnetic field sensing element that is configured to generate a second threshold signal; a first comparator that is configured to compare a reference signal to the first threshold signal and generate a first comparison signal; a second comparator that is configured to compare the reference signal to the second threshold signal and generate a second comparison signal; and a pulse-width modulating circuit (PWM circuit) that is configured to generate a pulse-width modulated signal (PWM signal) based on the first comparison signal and the second comparison signal; and a reference circuitry that is configured to generate the reference signal, the reference signal being a time-varying signal.

### BACKGROUND

As is known, sensors are used to perform various functions in a variety of applications. Some sensors include one or more electromagnetic flux sensing elements, such as a Hall effect element, a magnetoresistive element, or a receiving coil to sense an electromagnetic flux associated with a quantity that is desired to be monitored. Sensor integrated circuits are widely used in automobile control systems and other safety-critical applications. There are a variety of specifications that set forth requirements related to permissible sensor quality levels, failure rates, and overall functional safety.

### SUMMARY

According to aspects of the disclosure, a sensor is provided, comprising: a first magnetic field sensing element that is configured to generate a first threshold signal in response to a magnetic field; a second magnetic field sensing element that is configured to generate a second threshold signal in response to the magnetic field, the first magnetic field sensing element and the second magnetic field sensing element being so configured that the first threshold signal and the second threshold signal move in opposite directions in response to changes in the magnetic field; a first comparator that is configured to compare a reference signal to the first threshold signal, the first comparator being configured to generate a first comparison signal having a first value or a second value depending on an outcome of the comparison; a second comparator that is configured to compare the reference signal to the second threshold signal, the second comparator being configured to generate a second comparison signal having a third value or a fourth value depending on an outcome of the comparison; and a pulse-width modulating circuit (PWM circuit) that is configured to generate a pulse-width modulated signal (PWM signal) based on the first comparison signal and the second comparison signal, wherein the PWM circuit is configured to set the PWM signal to a fifth value when the first comparison signal assumes the second value in a first reference period, hold the PWM signal at the fifth value until the second comparison signal assumes the fourth value in a second reference period, and set the PWM signal to a sixth value in response to the second comparison signal assuming the fourth value; and a reference circuitry that is configured to generate the reference signal, the reference signal being a time-varying signal.

According to aspects of the disclosure, a sensor is provided comprising: a first sensing element that is configured to generate a first threshold signal in response to a magnetic field; a second sensing element that is configured to generate a second threshold signal in response to the magnetic field, the first sensing element and the second sensing element being so configured that the first threshold signal and the second threshold signal move in opposite directions in response to changes in the magnetic field; a comparator that is configured to receive a reference signal at a first input terminal of the comparator; a switching circuitry that is configured to toggle, in each of a plurality of reference periods, the first and second sensing elements between being disconnected and being coupled to a second input terminal of the comparator, such that in any given reference period only one of the first and second sensing elements is coupled to the second input terminal of the comparator, wherein the comparator is configured to: (i) compare the reference signal to one of the first threshold signal and the second threshold signal, depending on which one of the first sensing element and the second sensing element is currently coupled to the second input terminal and (ii) generate a comparison signal based on an outcome of the comparison, the comparison signal having a first value or a second value depending on the outcome of the comparison; a pulse-width modulating circuit (PWM circuit) that is configured to generate a pulse-width modulated signal (PWM signal) based on the comparison signal, wherein the PWM circuit is configured to set the PWM signal to a third value when the comparison signal assumes the second value in a first reference period, hold the PWM signal at the third value until the reference signal assumes the first value again in a second reference period, and set the PWM signal to a fourth value in response to the reference signal assuming again the second value in the second reference period; and a reference circuitry that is configured to generate the reference signal, the reference signal being a time-varying signal.

According to aspects of the disclosure, a sensor is provided, comprising: a first subcircuit including a first magnetic field sensing element that is coupled in series with a first capacitor, and a first switch that is configured to periodically discharge and charge the first capacitor, the first capacitor being charged with a signal that is generated by the first magnetic field sensing element in response to a magnetic field; a second subcircuit including a second magnetic field sensing element that is coupled in series with a second capacitor, and a second switch that is configured to periodically charge and discharge the second capacitor, the second capacitor being discharged concurrently with the first capacitor, the second capacitor being charged with a signal that is generated by the second magnetic field sensing element in response to the magnetic field, the second subcircuit and the first subcircuit being coupled to one another in a half-bridge configuration; and an electronic circuitry that is configured to: receive a first signal that is produced as a result of the first capacitor discharging, receive a second signal that is produced as a result of the second capacitor discharging, and generate a third signal based on the first signal and the second signal, the third signal being indicative of a magnitude of the magnetic field.

### BRIEF DESCRIPTION OF THE DRAWINGS

The foregoing features may be more fully understood from the following description of the drawings in which:

FIG. 1A is a diagram of an example of a sensor, according to aspects of the disclosure;

FIG. 1B is a state diagram illustrating aspects of the operation of the sensor of FIG. 1A, according to aspects of the disclosure;

FIG. 1C is a graph illustrating aspects of the operation of the sensor of FIG. 1A, according to aspects of the disclosure;

FIG. 1D is a graph illustrating aspects of the operation of the sensor of FIG. 1A, according to aspects of the disclosure;

FIG. 2A is a diagram of an example of a sensor, according to aspects of the disclosure;

FIG. 2B is a state diagram illustrating aspects of the operation of the sensor of FIG. 2A, according to aspects of the disclosure;

FIG. 2C is a state diagram illustrating aspects of the operation of the sensor of FIG. 2A, according to aspects of the disclosure;

FIG. 2D is a graph illustrating aspects of the operation of the sensor of FIG. 2A, according to aspects of the disclosure;

FIG. 3A is a diagram of an example of a system, according to aspects of the disclosure;

FIG. 3B is a diagram of an example of a sensor, according to aspects of the disclosure;

FIG. 3C shows a graph illustrating aspects of the operation of the sensor of FIG. 3B, according to aspects of the disclosure;

FIG. 3D is a diagram of an example of a sensor, according to aspects of the disclosure; and

FIG. 3E is a diagram of an example of a sensor, according to aspects of the disclosure.

### DETAILED DESCRIPTION

In one aspect, the present disclosure is directed to a method and system for encoding the voltage resulting from a magnetic signal sensed by two TMR elements, or another type of sensing elements, into a PWM waveform. PWM is a widely-used protocol that has several advantages, among which noise resistance is one of the most-highly valued. Unlike traditional magnetic field sensors, the sensing elements are not arranged in a classical bridge circuit. Rather, the sensing elements are arranged in what could be considered a half-bridge. This half-bridge circuit is arranged in such a way that the output of each of the two sensing elements is provided to one or more comparators. These comparators compare the voltage generated by the sensing elements to a controlled time-varying voltage. The outputs of the comparators are used to encode the PWM waveform.

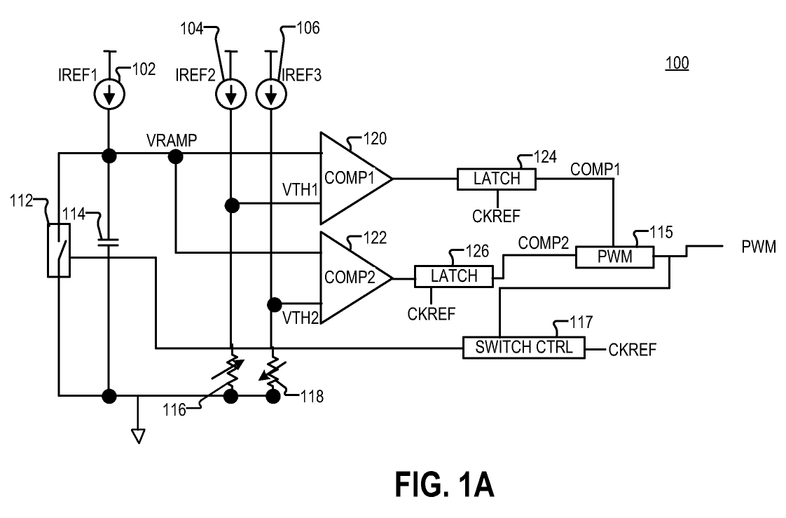

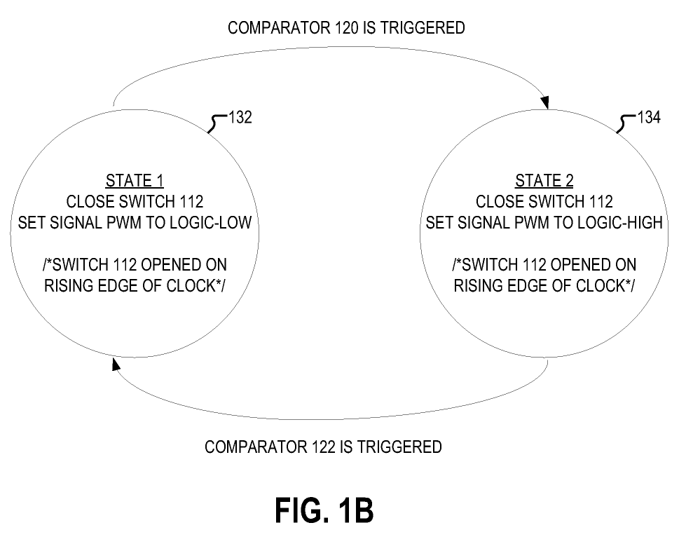

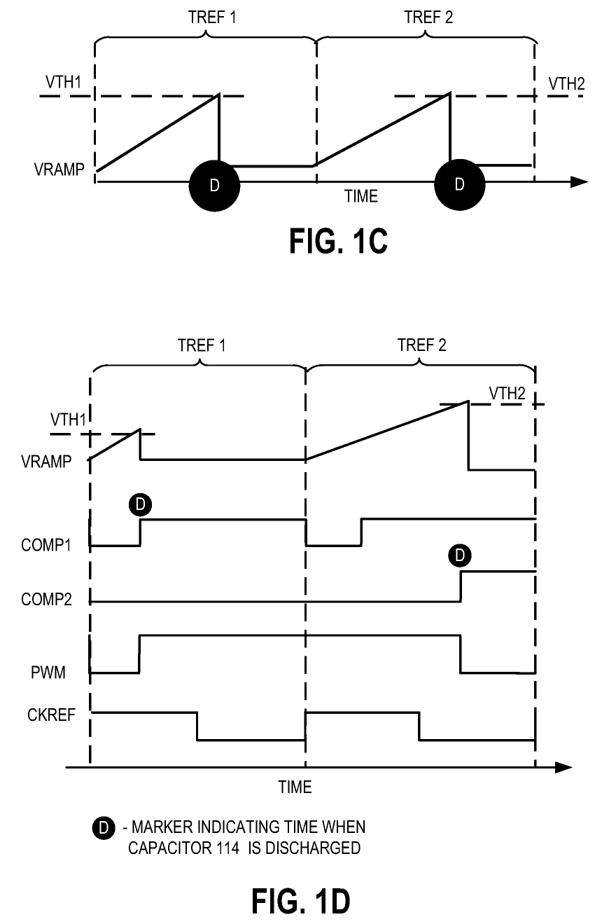

FIG. 1A is a diagram of an example of a sensor 100, according to aspects of the disclosure. As illustrated, the sensor 100 may include current sources 102, 104, and 106, comparators 120 and 122, a switch 112, latches 124 and 126, a pulse-width modulation (PWM) signal generator 115 (hereinafter “generator 115), a switch control circuit 117 (hereinafter “switch control 117”), a capacitor 114, and magnetic field sensing elements 116 and 118. Sensor 100 may be a current sensor, a position sensor, an angle sensor, and/or any other suitable type of magnetic field sensor.

As illustrated, current sources 104 and 106 may be arranged to energize sensing elements 116 and 118, respectively. Sensing element 116 may be arranged to generate a threshold signal VTH1 that is applied at a first input terminal of comparator 120. Sensing element 118 may be configured to generate a threshold signal VTH2 that is applied at a first input terminal of comparator of comparator 122. Signals VTH1 and VTH2 may be generated in response to a magnetic field that is incident on sensing elements 116 and 118. The magnetic field may be generated as a result of electrical current flowing through a conductor, as a result of a target moving, and/or in any other suitable manner. According to the present example, sensing elements 116 and 118 are tunneling magnetoresistance (TMR) elements, however alternative implementations are possible in which each of sensing elements 116 and 118 is an Indium Antimonide (InSb) element, a giant magnetoresistance (GMR) element, an anisotropic magnetoresistance element (AMR), a magnetic tunnel junction (MTJ), and/or any other suitable type of magnetic field sensing element. The present disclosure is not limited to any specific implementation of sensing elements 116 and 118.

Switch 112 may be a metal oxide semiconductor field effect transistor (MOSFET) and/or any other suitable type of switching device. Switch 112 may be coupled in parallel with capacitor 114 between current source 102 and ground. Switch 112 and capacitor 114 may be configured to generate a reference signal VRAMP by charging and discharging the capacitor 114 in a repetitive pattern. Signal VRAMP may be applied at a second input terminal of comparator 120 and a second input terminal of comparator 122. Comparator 120 may be configured to compare signal VRAMP to signal VTH1 and generate a signal COMP1 based on the outcome of the comparison. Signal COMP1 may have a first value (e.g., ‘0’) when VRAMP is less than VTH1 and a second value (e.g., ‘1’) when VRAMP is greater than VTH1. Comparator 122 may be configured to compare signal VRAMP to signal VTH2 and generate a signal COMP2 based on the outcome of the comparison. Signal COMP1 may have a third value (e.g., ‘0’) when VRAMP is less than VTH2 and a fourth value (e.g., ‘1’) when VRAMP is greater thanVTH2.

Latch 124 may be configured to latch signal COMP1 and provide it to generator 115. Latch 126 may be configured to latch signal COMP2 and provide it to generator 115. Generator 115 may generate a pulse-width-modulation-encoded signal (hereinafter “signal PWM”) based on signals COMP1 and COMP2. Both latches 124 and 126 may be driven with a clock signal CKREF. Switch control 117 may be configured to open the switch 112 on the rising edge of signal CKREF. Switch control 117 may be configured to close the switch 112 based on the values of signals COMP1 and COMP2 in the manner discussed further below with respect to FIG. 1B. In other words, switch control 117 may be configured to generate signal VRAMP by modulating the output of current source 102, wherein the modulation is performed by opening and closing switch 112. Each of generator 115 and switch control 117 may be implemented by using any suitable type of analog or digital circuitry. The present disclosure is not limited to any specific implementation of generator 115 and switch control 117.

FIG. 1B is a state diagram illustrating aspects of the operation of sensor 100. As illustrated, sensor 100 may be in one of a state 132 and a state 134. Sensor 100 may enter state 132 upon powering up. Sensor 100 may transition from state 132 into state 134 in response to comparator 120 being triggered. Sensor 100 may transition from state 134 back into state 132 in response to comparator 122 being triggered. In this example, comparator 120 is triggered when signal VRAMP becomes larger than signal VTH1 and/or signal COMP1 assumes the second value. In other words, in this example, comparator 120 is triggered when the output of comparator 120 changes as a result of signal VRAMP surpassing signal VTH1. In this example, comparator 122 is triggered when signal VRAMP becomes greater than signal VTH2 and/or signal COMP2 assumes the fourth value. In other words, in this example, comparator 122 is triggered when the output of comparator 122 changes as a result of signal VRAMP surpassing signal VTH2.

Upon sensor 100 entering state 132, switch control 117 may close switch 112, and generator 115 may set signal PWM to logic-low. Upon entering state 134, switch control 117 may close switch 112, and generator 115 may set signal PWM to logic-high. In other words, in any given run, the duration for which signal PWM remains at logic-high is equal to the length of the period starting when the value of signal VRAMP crosses the value of signal VTH1 and ending when the value of signal VRAMP crosses the value of signal VTH2. In this way, the duration for which signal PWM remains at logic-high encodes the magnitude of the magnetic field that is being applied.

FIG. 1C is a graph illustrating the state of sensor 100 when no magnetic field is being applied to sensing elements 116 and 118 (or when a zero magnetic field is applied to sensing elements 116 and 118). FIG. 1C illustrates that when the value of the magnetic field is zero, signals VTH1 and VTH2 have the same value. Furthermore, FIG. 1C illustrates that in a first reference period TREF 1, capacitor 114 is discharged (e.g., by closing switch 112) in response to the value of signal VRAMP crossing the value of signal VTH1, and in a second reference period TREF 2, capacitor 114 is discharged (e.g., by closing switch 112) in response to the value of signal VRAMP crossing the value of signal VTH2. Each of reference periods TREF 1 and TREF 2 may have a duration that is equal to the length of the period of clock signal CKREF. At the beginning of each reference period (or on each rising edge of clock signal CKREF), switch 112 is opened, which causes capacitor 114 to charge and signal VRAMP to start ramping up.

FIG. 1D is a graph illustrating the state of sensor 100 when a non-zero magnetic field is applied to sensing elements 116 and 118. FIG. 1D illustrates that when the value of the magnetic field is different from zero, the value of signal VTH1 may decrease, and the value of signal VTH2 may increase. The movement of signals VTH1 and VTH2 in opposite directions in response to the same magnetic field may be the result of sensing elements 116 and 118 having opposite pinning directions or as a result of sensing elements 116 and 118 being positioned in a certain way (e.g., on opposite sides of a conductor that generates the magnetic field as a result of electrical current flowing through it). Furthermore, FIG. 1D illustrates that when the value of signal VTH1 is lowered, the value of signal VRAMP may cross the value of signal VTH1 earlier in the reference period, and when signal VTH2 is increased, the value of signal VRAMP may cross the value of a signal VTH2 later in the reference period. Moreover, the amount by which signals VTH1 and VTH2 are increased or decreased depends on the magnitude of the magnetic field. In this regard, the temporal delay between the crossings of signals VTH1 and VTH2 by signal VRAMP may be proportional to the magnitude of the magnetic field. As noted above, generator 115 changes the state of signal PWM in response to these crossings, and in this way, it encodes the magnitude of the magnetic field in the pulse width of signal PWM. Specifically, the strength and direction of the magnetic field are encoded in the width of each PWM pulse, and a duty cycle of 50% of the PWM signal corresponds to a zero magnetic field.

FIG. 1D further shows graphs of signals COMP1, COMP2, PWM, and CKREF. As illustrated, when the value of signal VRAMP crosses the value of signal VTH1, signal COMP1 is latched at logic-high by latch 124 until the end of the current clock period. Similarly, when the value of signal VRAMP crosses the value of signal VTH2, signal COMP2 is latched at logic-high by latch 126 until the end of the current clock period. In a first reference period (e.g., TREF 1), while signal PWM is at logic-low, signal PWM is set to logic-high in response to signal VRAMP crossing signal VTH1 and/or signal COMP1 transitioning from the first value to the second value. The value of signal PWM is held at logic-high until the value of signal VRAMP crosses the value of signal VTH2 in a subsequent reference period (e.g., TREF 2). When, in the subsequent reference period, the value of signal VRAMP crosses the value of signal VTH2 and the value of signal COMP2 transitions from the third value to the second value, the value of signal PWM is set back to logic-low in response. In the present example, the subsequent reference period immediately follows the first reference period. However, the present disclosure is not limited thereto.

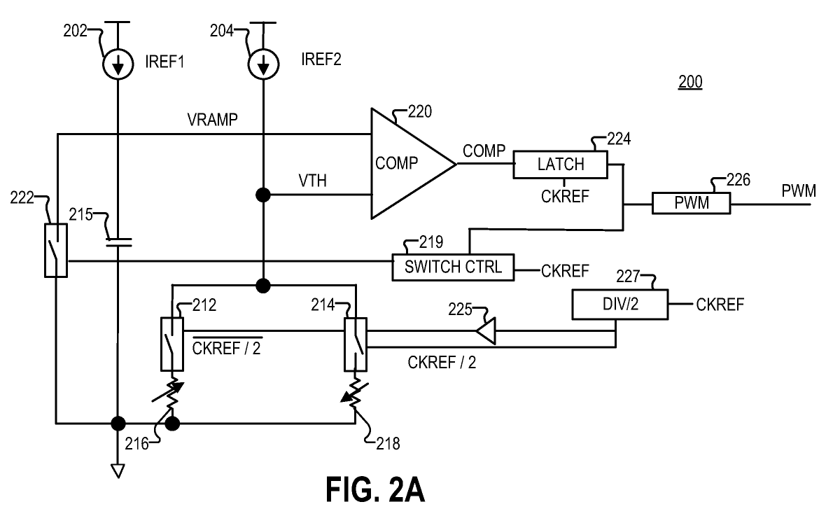

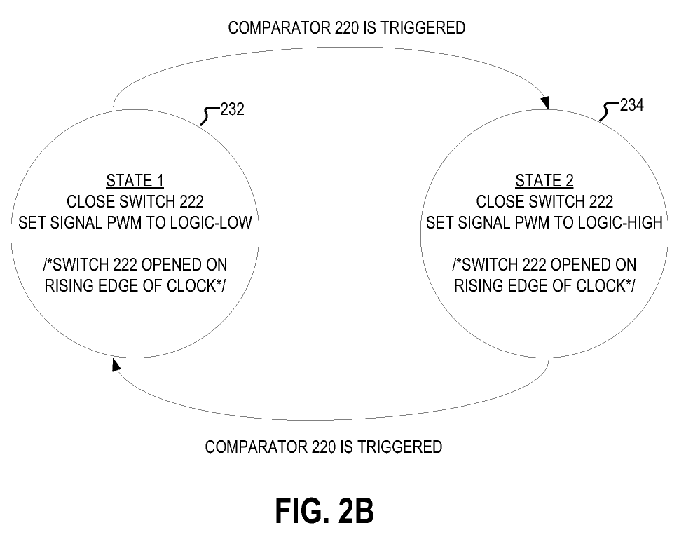

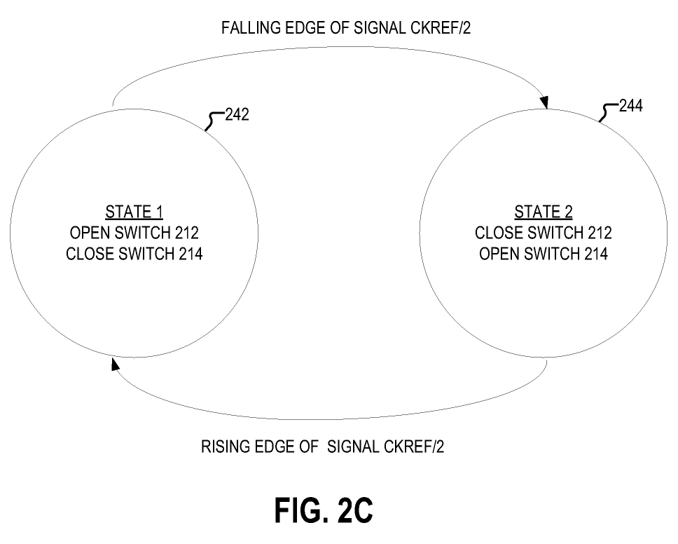

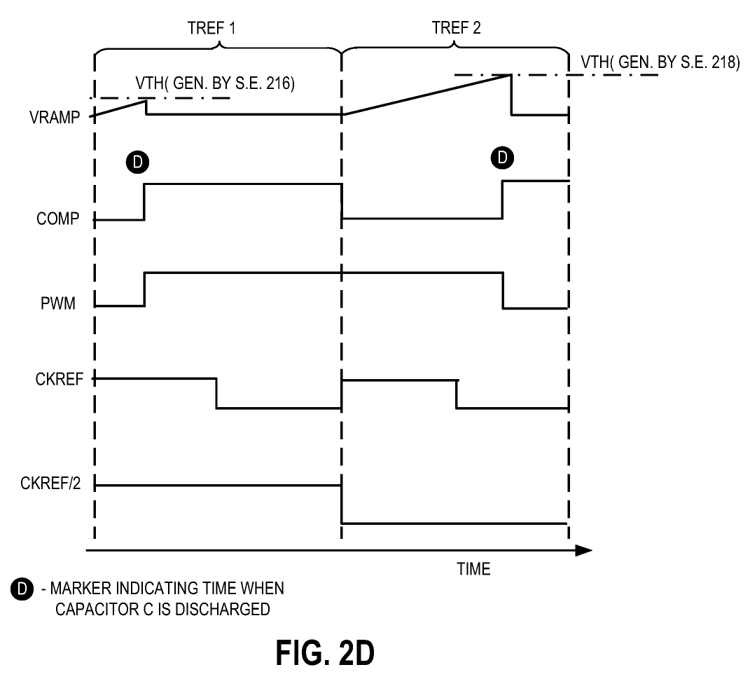

FIG. 2A is a diagram of a magnetic field sensor 200, according to aspects of the disclosure. Sensor 200 employs the same principle as sensor 100. However, sensor 200 utilizes a different architecture from that of sensor 100. In the architecture of sensor 200, a single current source is used to drive both magnetic field sensing elements, whereas in the architecture of sensor 100, each sensing element is driven with a different current source. As can be readily appreciated, the architecture of sensor 100 requires the current sources to be synchronized, whereas the architecture of sensor 200 does away with the need to perform any such synchronization, and for this reason, it may be considered advantageous.

Sensor 200 may include current sources 202 and 204, a comparator 220, a latch 224, a switch 222, switches 212 and 214, magnetic field sensing elements 216 and 218, capacitor 215, a PWM signal generator 226 (hereinafter “generator 226”), a switch control circuit 219 (hereinafter “switch control 219), a frequency divider circuit 227 (hereinafter “divider 227), and an inverter 225.

Current source 204 may be arranged to drive sensing elements 216 and 218. Sensing element 216 may be coupled in series with switch 212, as shown. Sensing element 218 may be coupled in series with switch 214, as shown. At any given time, one of switches 212 and 214 may be opened and the other one may be closed, such that only one of sensing elements 216 and 218 is coupled to one of the input terminals of comparator 220 and the other of sensing elements is disconnected from comparator 220. The one of sensing elements 216 and 218 that is coupled to the switch that is closed may generate a threshold signal VTH that is applied at a first input terminal of comparator 220. Each of switches 212 and 214 may be a MOSFET and/or any other suitable type of switching device.

Signal VTH may be generated in response to a magnetic field that is incident on sensing elements 216 and 218. The magnetic field may be generated as a result of electrical current flowing through a conductor, as a result of a target moving, and/or in any other suitable manner. According to the present example, sensing elements 216 and 218 are tunneling magnetoresistance (TMR) elements. However alternative implementations are possible in which each of sensing elements 216 and 218 is an Indium Antimonide (InSb) element, a giant magnetoresistance (GMR) element, an anisotropic magnetoresistance element (AMR), a magnetic tunnel junction (MTJ), and/or any other suitable type of magnetic field sensing element. The present disclosure is not limited to any specific implementation of sensing elements 216 and 218.

Switch 222 may be a metal oxide semiconductor field effect transistor (MOSFET) and/or any other suitable type of switching device. Switch 222 may be coupled in parallel with capacitor 215 between current source 202 and ground. Switch 222 and capacitor 215 may be configured to generate a reference signal VRAMP by charging and discharging the capacitor 215 in an alternating pattern. Signal VRAMP may be applied at a second input terminal of comparator 122. Comparator 220 may be configured to compare signal VRAMP to signal VTH and generate a signal COMP based on the outcome of the comparison. Signal COMP may have a first value (e.g., ‘0’) when VRAMP is less than VTH and a second value (e.g., ‘1’) when VRAMP is greater than VTH.

Latch 224 may be configured to latch signal COMP and provide it to generator 226. Generator 226 may generate a pulse-width-modulation-encoded signal (hereinafter “signal PWM”) based on signal COMP. Latch 224 may be driven with a clock signal CKREF. Switch control 219 may be configured to open switch 222 on the rising edge of signal CKREF. Switch control 219 may be configured to close the switch 224 based on the value of signal COMP in the manner discussed further below with respect to FIG. 2B. Switch control 219 may be configured to generate signal VRAMP by modulating the output of current source 102, wherein the modulation is performed by opening and closing switch 112. Each of generator 226 and switch control 219 may be implemented by using any suitable type of analog or digital circuitry. The present disclosure is not limited to any specific implementation of generator 226 and switch control 219.

Divider 227 may be configured to divide the frequency of clock signal CKREF. Divider 227 may receive signal CKREF as input and generate a signal CKREF/2 based on signal CKREF. Signal skref/2 may have half the frequency of signal CKREF. Inverter 225 may invert signal CKREF/2 to produce an inverted signal CKREF/2. Signal CKREF/2 may be used to open and close switch 214, and inverted signal CKREF/2 may be used to open and close switch 212. In one example, switch 214 may be closed when signal CKREF/2 is equal to logic-high and open when signal CKREF/2 is equal to logic-low. Similarly, switch 212 may be closed when signal CKREF/2 is equal to logic-low and open when signal CKREF/2 is equal to logic-high. At any given time, only one of switches 214 and 212 may be closed.

FIG. 2B is a state diagram illustrating aspects of the operation of sensor 200. As illustrated, sensor 200 may be in one of a state 232 and a state 234. Sensor 200 may enter state 232 upon powering up. Sensor 200 may transition from state 232 into state 234 in response to comparator 220 being triggered. Sensor 200 may transition from state 234 back into state 232 in response to comparator 220 being triggered (i.e., the next time comparator 220 is triggered). In the present example, comparator 220 is triggered when signal VRAMP becomes larger than signal VTH and/or signal COMP assumes the second value. In other words, in the present example, comparator 120 is triggered when the output of comparator 120 changes as a result of signal VRAMP surpassing signal VTH. Upon sensor 200 entering state 232, switch control 219 may close switch 222, and generator 226 may set signal PWM to logic-low. Upon entering state 234, switch control 219 may close switch 222, and generator 226 may set signal PWM to logic-high.

FIG. 2C is a state diagram illustrating aspects of the operation of sensor 200. As illustrated, sensor 200 may be in one of a state 242 and a state 244. Sensor 200 may enter state 242 upon powering up. Sensor 200 may transition from state 242 into state 244 on the falling edge of CKREF/2. Sensor 200 may transition from state 234 back into state 232 on the rising edge of signal CKREF/2. Upon sensor 200 entering state 242, switch 212 may be opened and switch 214 may be closed. Upon sensor 200 entering state 244, switch 212 may be closed and switch 214 may be opened.

FIG. 2D is a graph illustrating the state of sensor 200 when a non-zero magnetic field is applied to sensing elements 216 and 218. FIG. 2D illustrates that when the value of the magnetic field is different from zero, the value of a first instance of signal VTH may decrease and the value of a second instance of signal VTH may increase. The first instance of signal VTH is generated by using sensing element 216 and the second instance is generated by sensing element 218. The first instance of signal VTH is generated in a first reference period TREF 1 and the second instance is generated in a second reference period TREF 2. Each of reference periods TREF 1 and TREF 2 corresponds to a different period of the clock signal CKREF. The movement of the two instances of signal VTH in opposite directions in response to the same magnetic field may be the result of sensing elements 216 and 218 having opposite pinning directions or being positioned in a certain way (e.g., on opposite sides of a conductor that generates the magnetic field as a result of electrical current flowing through it). Moreover, the amount by which each instance of signal VTH is increased or decreased depends on the magnitude of the magnetic field. In this regard, the temporal delay between the crossings of the instances of signal VTH by signal VRAMP may be proportional to the magnitude of the magnetic field. As noted above, generator 226 changes the state of signal PWM in response to these crossings and in this way it encodes the magnitude of the magnetic field in the pulse width of signal PWM. Specifically, the strength and direction of the magnetic field are encoded in the width of each PWM pulse, and a duty cycle of 50% of the PWM signal corresponds to a zero magnetic field.

FIG. 2D further shows graphs of signals COMP, PWM, CKREF, and CKREF/2. As illustrated, when the value of signal VRAMP crosses the value of signal VTH, signal COMP is latched at logic-high by latch 224 until the end of the current clock period. In a first reference period (e.g., TREF 1), while signal PWM is set to logic-low, the value of signal VRAMP crosses the value of signal VTH, signal COMP is set to the second value, and signal PWM is set to logic-high. The value of signal PWM is held at logic-high until the value of signal VRAMP crosses the value of signal VTH in a subsequent reference period (e.g., TREF 2). When, in the subsequent reference period, the value of signal VRAMP crosses the value of signal VTH and signal COMP is again set to the second value, the value of signal PWM is set back to logic-low. In the present example, the subsequent reference period immediately follows the first reference period.

In some implementations, the values the current IREF2 which is supplied by current source 204 may be selected and the maximum resistance values of sensing elements 216 and 216 may be selected in such a way that the product of the current IREF2 and the maximum resistance values is lower than the supplied voltage of sensor 200. In some implementations, the values the current IREF1 which is supplied by current source 202 may be selected and the maximum resistance values of sensing elements 216 and 216 may be selected in such a way that the product of the current IREF1 and the maximum resistance values is lower than the supply voltage of sensor 200. This may ensure that the threshold VTH would be crossed by signal VRAMP in a next reference period.

As noted above, the sensing elements in each of sensors 100 and 200 are arranged to respond differentially to an applied magnetic field. In some respects, using two sensing elements in the manner discussed with respect to sensors 100 and 200 is advantageous because it allows for the rejection of common mode environmental conditions such as temperature, package stresses, stray fields, which will not affect the duty cycle of the output waveform.

Considering the example of FIG. 1A, when a common mode environmental condition, like a stray field affects both sensing elements the same way, then both VTH1 and VTH2 will shift the same way too. However, as noted above, signals VTH1 and VTH2 tend to move in opposite directions in response to a magnetic field of interest (i.e., the magnetic field that is being measured), and the width of the PWM pulse that encodes the strength of the magnetic field is based on the difference between signals VTH1 and VTH2. Any movement in the same direction of signals VTH1 and VTH2 in response to a stray field (or another common mode environmental condition) would not affect this difference and therefore would not have an effect on the width of the PWM pulse.

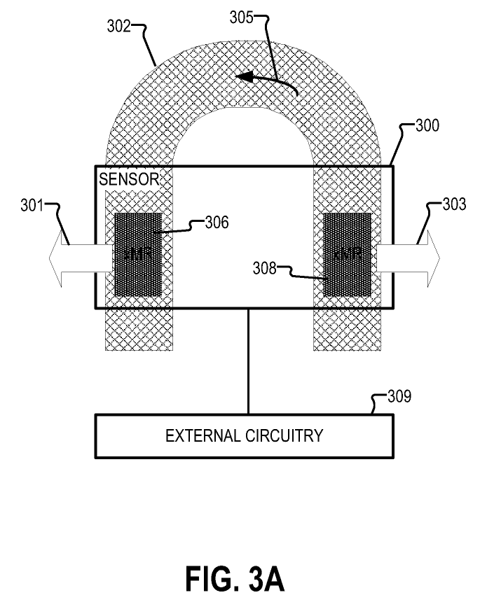

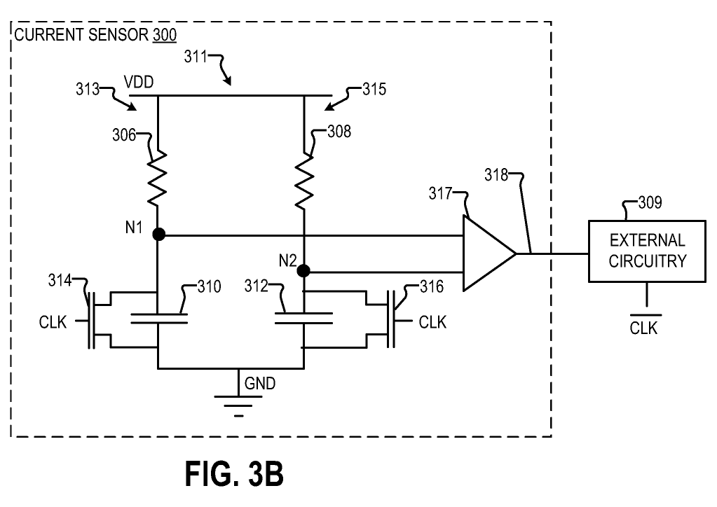

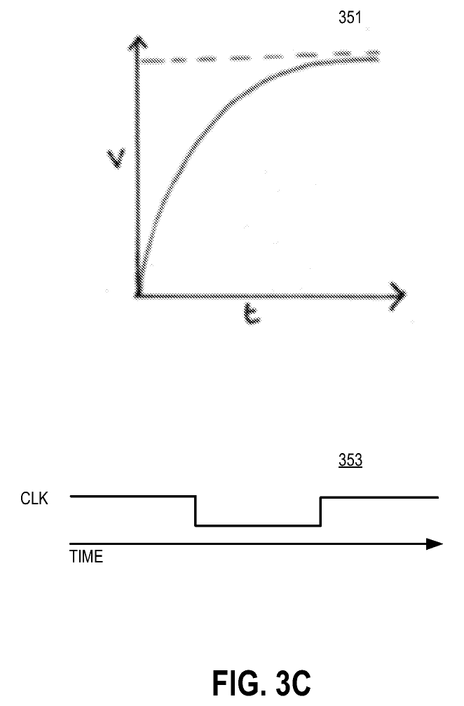

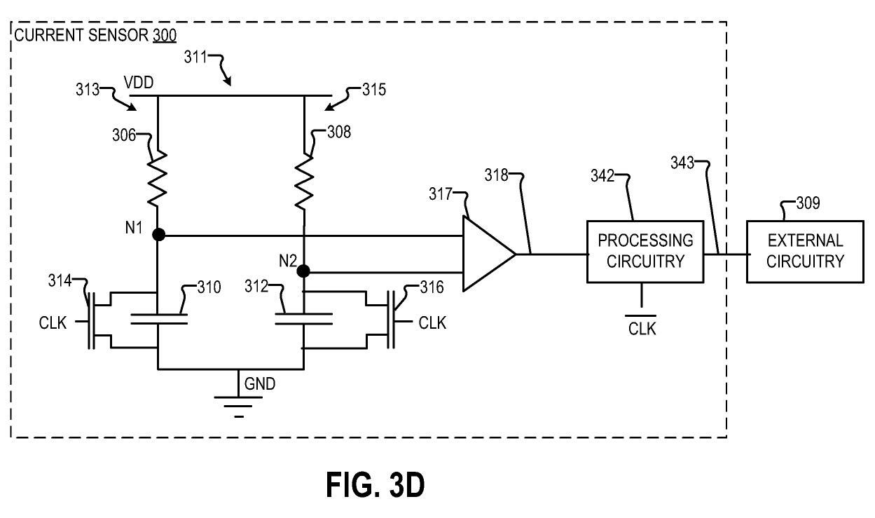

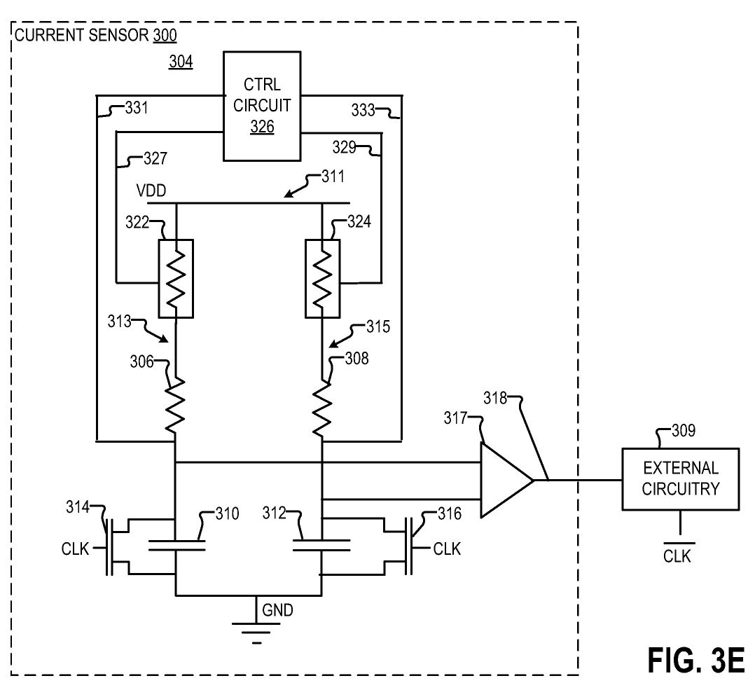

FIG. 3A is a diagram illustrating aspects of the operation of a current sensor 300, according to aspects of the disclosure. Sensor 300 is configured to detect the level of electrical current through a conductor 302. Sensor 300 uses a different measurement mechanism than conventional current sensors. Sensor 300 uses sensing elements 306 and 308, which are arranged in a half-bridge configuration, to detect very small currents through the conductor 302. Each of sensing elements 306 and 308 is configured to charge a different capacitor at a rate proportional to the magnitude of a magnetic field that is incident on sensing elements 306 and 308. At the end of each charging cycle, the capacitors are drained into external circuitry 309. External circuitry 309 may include electronic circuitry that is configured to control the operation of a machine or an electronic device based on the level of electrical current through conductor 302. External circuitry 309 may be configured to use sensor 300 to measure the level of electrical current through conductor 302.

According to the present example, sensing elements 306 and 308 are tunneling magnetoresistance (TMR) elements, however alternative implementations are possible in which each of sensing elements 306 and 308 is an Indium Antimonide (InSb) element, a giant magnetoresistance (GMR) element, an anisotropic magnetoresistance element (AMR), a magnetic tunnel junction (MTJ), and/or any other suitable type of magnetic field sensing element. The present disclosure is not limited to any specific implementation of sensing elements 306 and 308. TMR resistors can be high in value and have a lot of change with a small stimulus.

According to the present example, sensing elements 306 and 308 have the same pinning direction. The direction of the magnetic field produced by conductor 302 at the location of sensing element 306 is indicated by arrow 301, the direction of the magnetic field generated by conductor 302 is indicated by arrow 303, and the direction of flow of electrical current through conductor 302 is indicated by arrow 305. Although, in the example of FIG. 3A, conductor 302 is U-shaped, in alternative implementations, conductor 302 may be straight. In such implementations, sensing elements 306 and 308 may have opposite pinning directions.

FIG. 3B is a diagram of sensor 300, in accordance with one implementation. As illustrated, sensor 300 may include a half-bridge circuit 311 and an amplifier 317. Half-bridge circuit 311 may include legs 313 and 315. Leg 313 may include sensing element 306, a MOSFET 314, and a capacitor 310. Leg 315 may include sensing element 308, a MOSFET 316, and a capacitor 312. Half-bridge circuit 311 may be powered by a voltage source VDD. Legs 313 and 315 may be coupled in parallel between the voltage source VDD and ground. Node N1 of leg 313 may be coupled to a first input terminal of an amplifier 317. Node N2 of leg 315 may be coupled to amplifier 317. Signal 318, which is output by amplifier 317, may be provided to external circuitry 309. The signal 318, may be a differential signal that is based on the difference between the signal that is output on node N1 of leg 313 and the signal that is output on node N2 of leg 315. As can be readily appreciated, signal 318 may be indicative of the level of electrical current through conductor 302. In some implementations, by making the resistance of sensing elements 306 and 308 large enough, and making capacitors 310 and 312 small enough, a significant enough charge may accumulate in capacitors 310 and 312 to measure very small currents through conductor 302 by “integrating” them over a given time interval.

Each of MOSFETs 314 and 316 may be operated as a switch. Each of MOSFETs 314 and 316 may be turned on the rising edge of a clock signal CLK and turned off at the falling edge of clock signal CLK. Clock signal CLK may have a square waveform, as illustrated by graph 353 (shown in FIG. 3C). When MOSFETs 314 and 316 are turned off, capacitors 310 and 312 are being charged by sensing elements 306 and 308, respectively. When MOSFETs 314 and 316 are turned on, capacitors 310 and 312 are discharged. External circuitry may sample signal 318 while the clock signal CLK is at logic-low and use the sampled signal to determine the level of electrical current through conductor 302 and/or to make adjustments to the operation of the device or machinery that is being controlled by external circuitry 309. Although, in the present example, MOSFETs are used to charge and discharge the capacitors 310 and 312, alternative implementations are possible in which a different type of switching device is used instead.

Graph 351 which is shown in FIG. 3C shows the RC curve of capacitors 310 and 312. FIG. 3C shows that capacitors 310 and 312 charge in a non-linear fashion for the same RC time constant. Because signal 318 is a differential signal, this will help offset the effects of the internal resistance of capacitors 310 and 312. However, because circuit 311 is not a full Wheatstone bridge, this arrangement may need to be calibrated once or periodically. The calibration may be performed by a processing circuitry 342, which is shown in FIG. 3D. The calibration may involve adjusting the values of resistors 306 and 308, to select the time when the responses of nodes N1 and N2 cross so as to ensure true measurement.

FIG. 3D is a diagram of sensor 300 in accordance with another configuration. The configuration of sensor 300 that is shown in FIG. 3D is identical to the configuration shown in FIG. 3B, but for including a processing circuitry 342. Processing circuitry 342 may include one or more of: at least one amplifier, at least one analog-to-digital converter, at last one digital-to-analog converter, an output interface (e.g., an I2C interface, etc.), a digital controller, circuitry that is configured to perform temperature compensation, gain removal, or offset correction on signal 318, and/or any other suitable type of analog or digital circuitry that is customarily found in current sensors. In one example, processing circuitry 342 may sample the signal 318 during periods in which the clock signal CLK is set to logic-low (i.e., in periods when the capacitors 310 and 312 are being discharged). Processing circuitry 342 may process the sampled signal to generate a signal 343 and provide the signal 343 to external circuitry 309. Signal 343 may be indicative of the level of electrical current through conductor 302 and it may be used by external circuitry 309 to adjust the operation of the machinery or device whose operation is controlled by external circuitry 309.

FIG. 3E is a diagram of sensor 300 in accordance with another configuration. The configuration of sensor 300 that is shown in FIG. 3E is identical to the configuration shown in FIG. 3B, but for including variable resistors 322 and 324, and a control circuit 326. Resistor 322 may be coupled in series with sensing element 306 in leg 313. Resistor 324 may be coupled in series with sensing element 308 in leg 315. Control circuitry 326 may include any suitable type of analog or digital circuitry. Control circuitry 326 may generate control signals 327 and 329. Control signal 327 may set the resistance of resistor 322 and control signal 329 may set the resistance of resistor 324. In some implementations, control circuitry 326 may be configured to dynamically adjust the respective resistances of resistors 322 and 324 in order to linearize the voltage-versus-time profile of signal 318 during periods in which capacitors 310 are being discharged.

In one example, control circuitry 326 may monitor (e.g, via lines 331 and 333) the voltage at the high side of capacitor 310 (and/or capacitor 312). When capacitor 310 (and/or capacitor 312) is more empty, control circuitry 326 may be increase the resistance of resistor 322 (and/or resistor 324). As capacitor 310 (and/or capacitor 312) charges, control circuitry 326 may decrease the resistance of resistor 322 increasing the charging rate of capacitor 310 (and/or capacitor 312). By dynamically adjusting the resistance of resistors 322 and 324, control circuitry 326 may achieve a more linear voltage versus time. Additionally, or alternatively, in some implementations, the resistance of each of resistors 322 and 324 may be inversely proportional to the time for which capacitors 310 and 312 are being discharged. The discharge time may depend on switches 314 and 316.

FIGS. 1A-3E are provided as an example only. Throughout the disclosure, like reference numerals refer to like parts. The examples provided with respect to FIGS. 1A-3E are not mutually exclusive and may be combined, modified, or adapted in various ways by those skilled in the art without departing from the scope and spirit of the invention defined by the appended claims. In general, the logic that is illustrated in the example of FIGS. 1A-3E may be inverted, such that elements that are driven on the rising edge of a signal are driven on the falling edge of the same signal. For example, in the example of FIG. 1A, signal PWM may be set to logic low when VRAMP crosses VTH1 and back to logic-high when VRAM crosses VTH2 in a second reference period.

A magnetic-field sensing element can be, but is not limited to, a Hall Effect element a magnetoresistance element, or an inductive coil. As is known, there are different types of Hall Effect elements, for example, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb). The phrase “set of magnetic field elements” shall mean “one or more magnetic field sensing elements”.

The concepts and ideas described herein may be implemented, at least in part, via a computer program product, (e.g., in a non-transitory machine-readable storage medium such as, for example, a non-transitory computer-readable medium), for execution by, or to control the operation of, data processing apparatus (e.g., a programmable processor, a computer, or multiple computers). Each such program may be implemented in a high-level procedural or object-oriented programming language to work with the rest of the computer-based system. However, the programs may be implemented in assembly, machine language, or Hardware Description Language. The language may be a compiled or an interpreted language, and it may be deployed in any form, including as a stand-alone program or as a module, component, subroutine, or another unit suitable for use in a computing environment. A computer program may be deployed to be executed on one computer or multiple computers at one site or distributed across multiple sites and interconnected by a communication network. A computer program may be stored on a non-transitory machine-readable medium that is readable by a general or special-purpose programmable computer for configuring and operating the computer when the non-transitory machine-readable medium is read by the computer to perform the processes described herein. For example, the processes described herein may also be implemented as a non-transitory machine-readable storage medium, configured with a computer program, where upon execution, instructions in the computer program cause the computer to operate in accordance with the processes. A non-transitory machine-readable medium may include but is not limited to a hard drive, compact disc, flash memory, non-volatile memory, or volatile memory. The term unit (e.g., an addition unit, a multiplication unit, etc.), as used throughout the disclosure may refer to hardware (e.g., an electronic circuit) that is configured to perform a function (e.g., addition or multiplication, etc.), software that is executed by at least one processor, and configured to perform the function, or a combination of hardware and software.

Also, for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements. Like reference numerals refer to like elements.

As used herein in reference to an element and a standard, the term “compatible” means that the element communicates with other elements in a manner wholly or partially specified by the standard, and would be recognized by other elements as sufficiently capable of communicating with the other elements in the manner specified by the standard. The compatible element does not need to operate internally in a manner specified by the standard.

Having described preferred embodiments, which serve to illustrate various concepts, structures and techniques, which are the subject of this patent, it will now become apparent that other embodiments incorporating these concepts, structures and techniques may be used. Accordingly, it is submitted that the scope of the patent should not be limited to the described embodiments but rather should be limited only by the spirit and scope of the following claims.

1. A sensor, comprising:
a first magnetic field sensing element that is configured to generate a first threshold signal in response to a magnetic field;
a second magnetic field sensing element that is configured to generate a second threshold signal in response to the magnetic field, the first magnetic field sensing element and the second magnetic field sensing element being so configured that the first threshold signal and the second threshold signal move in opposite directions in response to changes in the magnetic field;
a first comparator that is configured to compare a reference signal to the first threshold signal, the first comparator being configured to generate a first comparison signal having a first value or a second value depending on an outcome of the comparison;
a second comparator that is configured to compare the reference signal to the second threshold signal, the second comparator being configured to generate a second comparison signal having a third value or a fourth value depending on an outcome of the comparison; and
a pulse-width modulating circuit (PWM circuit) that is configured to generate a pulse-width modulated signal (PWM signal) based on the first comparison signal and the second comparison signal, wherein the PWM circuit is configured to set the PWM signal to a fifth value when the first comparison signal assumes the second value in a first reference period, hold the PWM signal at the fifth value until the second comparison signal assumes the fourth value in a second reference period, and set the PWM signal to a sixth value in response to the second comparison signal assuming the fourth value; and
a reference circuitry that is configured to generate the reference signal, the reference signal being a time-varying signal.

2. The sensor of claim 1, wherein the reference circuitry includes a capacitor and a switch control circuit that is arranged to assume a first state in response to the second comparison signal being set to the fourth value, and assume a second state in response to the first comparison signal being set to the second value, such that when the switch control circuit is in the first state, the switch control circuit discharges the capacitor based on the second threshold signal and when the switch control circuit is in the second state, the switch control circuit discharges the capacitor based on the first threshold signal.

3. The sensor of claim 2, wherein the reference circuitry further includes a switch that is coupled in parallel with the capacitor between a power source and ground, and discharging the capacitor includes closing the switch.

4. The sensor of claim 3, wherein the switch is opened in response to a clock signal transitioning from a first clock signal value to a second clock signal value, and closed in response to the first comparison signal transitioning from the second value to the first value or in response to the second comparison signal transitioning from the fourth value to the third value, depending on which one of the first state and the second state the switch control circuit is in.

5. The sensor of claim 4, wherein the first reference period corresponds to a first period of the clock signal, the second reference period corresponds to a second period of the clock signal, and the second period of the clock signal immediately follows the first period of the clock signal; and

6. The sensor of claim 1, wherein the first magnetic field sensing element includes a first tunneling magnetoresistance (TMR) element and the second magnetic field sensing element includes a second TMR element.

7. The sensor of claim 1, wherein each of the second value, the fourth value, and the fifth value is a logic-high value, and each of the first value, the third value, and the sixth value is a logic-low value.

8. A sensor, comprising:
a first sensing element that is configured to generate a first threshold signal in response to a magnetic field;
a second sensing element that is configured to generate a second threshold signal in response to the magnetic field, the first sensing element and the second sensing element being so configured that the first threshold signal and the second threshold signal move in opposite directions in response to changes in the magnetic field;
a comparator that is configured to receive a reference signal at a first input terminal of the comparator;
a switching circuitry that is configured to toggle, in each of a plurality of reference periods, the first and second sensing elements between being disconnected and being coupled to a second input terminal of the comparator, such that in any given reference period only one of the first and second sensing elements is coupled to the second input terminal of the comparator, wherein the comparator is configured to: (i) compare the reference signal to one of the first threshold signal and the second threshold signal, depending on which one of the first sensing element and the second sensing element is currently coupled to the second input terminal and (ii) generate a comparison signal based on an outcome of the comparison, the comparison signal having a first value or a second value depending on the outcome of the comparison;
a pulse-width modulating circuit (PWM circuit) that is configured to generate a pulse-width modulated signal (PWM signal) based on the comparison signal, wherein the PWM circuit is configured to set the PWM signal to a third value when the comparison signal assumes the second value in a first reference period, hold the PWM signal at the third value until the reference signal assumes the first value again in a second reference period, and set the PWM signal to a fourth value in response to the reference signal assuming again the second value in the second reference period; and
a reference circuitry that is configured to generate the reference signal, the reference signal being a time-varying signal.

9. The sensor of claim 8, wherein the reference circuitry includes a capacitor and a switch control circuit that is arranged to switch between a first state and a second state in response to the comparator being triggered, the comparator being triggered when the comparison signal is set to the second value.

10. The sensor of claim 9, wherein the reference circuitry further includes a switch that is coupled in parallel with the capacitor between a power source and ground, and discharging the capacitor includes closing the switch.

11. The sensor of claim 10, wherein the switch is opened in response to a clock signal transitioning from a first clock signal value to a second clock signal value, and the switch is closed in response to the comparison signal transitioning from the first value to the second value.

12. The sensor of claim 11, wherein the first reference period corresponds to a first period of the clock signal, the second reference period corresponds to a second period of the clock signal, and the second period of the clock signal immediately following the first period of the clock signal.

13. The sensor of claim 12, wherein the first sensing element includes a first tunneling magnetoresistance (TMR) element and the second sensing element includes a second tunneling magnetoresistance element.

14. The sensor of claim 13, wherein each of the second value and the third value is a logic-high value and each of the first value and the fourth value is a logic-low value.

15. A sensor, comprising:
a first subcircuit including a first magnetic field sensing element that is coupled in series with a first capacitor, and a first switch that is configured to periodically discharge and charge the first capacitor, the first capacitor being charged with a signal that is generated by the first magnetic field sensing element in response to a magnetic field;
a second subcircuit including a second magnetic field sensing element that is coupled in series with a second capacitor, and a second switch that is configured to periodically charge and discharge the second capacitor, the second capacitor being discharged concurrently with the first capacitor, the second capacitor being charged with a signal that is generated by the second magnetic field sensing element in response to the magnetic field, the second subcircuit and the first subcircuit being coupled to one another in a half-bridge configuration; and
an electronic circuitry that is configured to: receive a first signal that is produced as a result of the first capacitor discharging, receive a second signal that is produced as a result of the second capacitor discharging, and generate a third signal based on the first signal and the second signal, the third signal being indicative of a magnitude of the magnetic field.

16. The sensor of claim 15, wherein each of the first magnetic field sensing element and the second magnetic field sensing element includes a tunneling magnetoresistance (TMR) element.

17. The sensor of claim 15, wherein:
the first subcircuit includes a first variable resistor that is coupled in series with the first magnetic field sensing element, the first variable resistor having a first resistance that is varied based on an amount of charge that is present in the first capacitor;
the second subcircuit includes a second variable resistor that is coupled in series with the second magnetic field sensing element, the second variable resistor having a second resistance that is varied based on an amount of charge that is present in the second capacitor; and
the first and second variable resistors are arranged to linearize a voltage-versus-time profile of the output signal.

18. The sensor of claim 15, wherein:
the first subcircuit includes a first variable resistor that is coupled in series with the first magnetic field sensing element;
the second subcircuit includes a second variable resistor that is coupled in series with the second magnetic field sensing element; and
a control circuit that is configured to linearize a voltage-versus-time profile of the output signal by varying the respective resistances of the first variable resistor and the second variable resistor.

19. The sensor of claim 15, wherein the first and second subcircuits are coupled in parallel between a voltage source and ground.

20. The sensor of claim 15, wherein the magnetic field is generated as a result of electrical current flowing through a conductor, and the third signal is indicative of a level of the electrical current.
